(19) United States
(12) Patent Application Publication
(10) Pub. No.: US 2023/0007808 A1
(43) Pub. Date: Jan. 5, 2023

(54) TELECOMMUNICATIONS HOUSING WITH IMPROVED THERMAL LOAD MANAGEMENT

(71) Applicant: NetComm Wireless Pty Ltd, Lane Cove (AU)

(72) Inventors: James Lau, Lane Cove (AU); Paul Mathieu, Lane Cove (AU)

(21) Appl. No.: 17/901,187

(22) Filed: Sep. 1, 2022

Related U.S. Application Data
(63) Continuation of application No. PCT/AU2021/050202, filed on Mar. 5, 2021.

(30) Foreign Application Priority Data
Mar. 6, 2020 (AU) 2020900704
Sep. 8, 2020 (AU) 2020903220

(51) Int. Cl. H05K 7/20; H01Q 1/02

(52) U.S. Cl. CPC H05K 7/20127; H05K 7/20154; H01Q 1/02

(57) ABSTRACT

An outdoor-mountable, telecommunications module, comprising: an environmentally hardened housing; telecommunications equipment encased within the housing and disposed for rotation about an axis within the housing; and a thermal load mitigation system employing (i) a heat spreader structure for thermal conduction of heat away from at least some heat-generating components of the telecommunications equipment, to a rotatable heat sink structure received within the housing, (ii) an arrangement for primarily thermal conduction of heat across a small air gap between the rotatable heatsink structure and a non-rotating heat sink structure collocated within the housing, and (iii) an arrangement for convective heat dissipation into the environment from a radiator structure disposed outside of the housing and which is in direct thermal conductive arrangement with the non-rotating heat sink structure disposed inside of the housing.

### CROSS-REFERENCES TO RELATED APPLICATIONS

This application is a continuation application of International Patent Application No. PCT/AU2021/050202 entitled “TELECOMMUNICATIONS HOUSING WITH IMPROVED THERMAL LOAD MANAGEMENT,” filed on Mar. 5, 2021, which claims priority to Australian Patent Application No. 2020903220, filed on Sep. 8, 2020, and Australian Patent Application No. 2020900704, filed on Mar. 6, 2020, each of which are herein incorporated by reference in their entirety for all purposes.

### FIELD OF THE INVENTION

The present invention is concerned with the removal of heat from heat-generating electric and electronic components of telecommunications equipment received within an environmentally hardened housing. In a more specific aspect, the invention is concerned with wireless telecommunication equipment which is deployed outdoors and susceptible to environmental conditions requiring the use of environmentally hardened housings.

### BACKGROUND OF THE INVENTION

Fixed wireless services typically use directional radio antennas on each end of a signal transmission channel. Such antennas are often mounted to buildings, transmission/repeater towers, poles, etc. Because they are designed for an outdoor environment, telecommunication antennas are typically housed in radomes or other housings that are weatherproof (i.e. environmentally hardened) to protect the delicate electronic and electric components associated with the antennas from ambient conditions such as rain, debris, air pollution, etc., while still permitting the unhindered propagation of electromagnetic radiation, particularly radio waves, to and from the protected antenna.

Development of Multiple Input Multiple Output (MIMO) technology for fixed wireless telecommunication systems, including 4G LTE (Long Term Evolution), has meant that a comparatively larger number of power-consuming, heat generating electronic components are housed in a common housing with the various antennas used. Typically, outdoors mounted enclosures for wireless transmission equipment, such as 4G LTE routers/modems, MIMO antenna base stations and modems, and the like, as well as stationary user equipment installed at (end) user premises, need to be rated ‘dust and water tight’ (e.g. IP65 standard). Meeting such requirements in turn makes the removal of heat generated by the electronic and electric components from within the housing and its dissipation/transfer into the surrounding ambient air difficult. Fan forced convection cooling systems typically employed in the computer industry are unsuitable for use in the essentially hermetically sealed enclosures of 4G outdoor antenna equipment/modems.

In conventional, directional wireless transceiver units/modems, heat generated by electronic circuits and other components typically received on a printed circuit board (PCB) and associated with the antenna elements, is conducted to a (metallic) finned heat sink mounted on the side of the enclosure or housing opposite the radiating antenna elements. For that purpose, one or more heat conducting bodies are placed in direct contact with the heat generating components at the PCB as well as the heat sink. Waste heat, which if not efficiently removed adversely affects the performance of the electronics, is thus first conducted from within the housing to the heat sink from where it is in turn transferred into the ambient surroundings (air) by convection and radiation.

The introduction of 5G, the 5th generation of mobile networks, requires a more dense deployment of outdoor modem/repeater/router units, hereinafter simply called mini base stations for ease of reference, which are specifically designed for the very localised wireless coverage of 5G, typically from 10 to a few hundred meters. These mini base stations provide ‘in-fill stations’ for the larger macro network. These small cells and user equipment (UE) are essential for 5G networks as the mmWave frequencies 5G employs have a very short connection range.

Deployment of 4G LTE and 5G systems in their application in fixed wireless access and the desire/need to maintain reverse compatibility with 3G and 4G systems, thereby to service a larger number of frequency bandwidths, also means that dedicated outdoor 4G LTE and 5G mini base stations will typically have an increased number of electronic and antenna components received within a common housing.

The increase in electronic components to operate the various antennas for the specific frequency band widths allocated to 3G, 4G, 4G LTE and 5G, in particular where such are mounted on a common PCB as is planned, in turn means not only an increase in power consumption and thus heat generation within the sealed housing, but also increased heat source densities within a relatively small foot print enclosure/housing.

Noting that 4G LTE/5G outdoor fixed wireless mini base stations are to have an as small as possible form factor for the housing, inclusive of associated thermal load dissipating arrangements, it will be necessary to devise improved thermal load dissipation strategies to take account of the increased power consumption and heat generation of such units.

An additional issue arises from the use of the mmWave frequency bands in 5G. Signals transmitted in the mmWave frequency bandwidth ‘bounce’ a lot during the day, either due to localised atmospheric changes or the temporary presence of objects in the radiation paths between mini base stations. In order to maintain optimal antenna performance in receiving/transmitting signals, re-orientation (about an axis in the radiation plane of the antenna(s) incorporated in the fixed modem/mini base station units) will need to take place more often than with traditional antennas used eg in 3G networks. It would be impractical to provide for manual re-orientation of the entire unit, therefore necessitating some mechanism that allows for automated mechanical re-orientation of mini base stations and UEs, without compromising the thermal load dissipation arrangement.

### SUMMARY OF THE INVENTION

In accordance with a first aspect, the present invention provides an outdoor-mountable, telecommunications module, such as a fixed wireless modem/router module, comprising an environmentally hardened housing, telecommunications equipment encased within the housing and disposed for rotation about an axis within the housing, and a thermal load mitigation system employing (i) thermal conduction of heat from at least some heat-generating components of the telecommunications equipment which in one non-limiting embodiment comprises a PCB including mmWave antenna signal generation and processing components providing a plurality of heat sources, as well as signal radiators/receivers (antennas), to a rotatable heat sink received within the housing, (ii) primarily conductive heat transfer across a small air gap between the rotatable heatsink and a non-rotating, stationary heat sink component collocated within the housing, and (iii) convective heat dissipation into the environment from a radiator disposed outside of the housing and which is in direct heat conductive connection with the non-rotating heat sink component disposed inside of the housing.

In the context of telecommunications equipment suitable for coverage of 3G, 4G, 4G LTE and 5G bandwidths, most if not all of the processors (ICs) used for 3G and 4G functionality generate a level of heat that can be allowed to radiated into the inside of the housing without a need to use dedicated heat mitigation or removal arrangements. Typically experienced heat loads are ultimately able to be ‘dissipated’ through the housing walls into the surrounding environment without raising the temperature within the housing to a degree adversely affecting operation of the electronic processors.

On the other hand, however, processors for 5G implementation generate heat amounts that require the use of dedicated heat transfer (i.e. removal) arrangements capable of removing larger heat amounts in shorter periods of time and direct the heat into the rotatable heat sink (as will be described in more detail below), then from the latter into the stationary heat sink that cooperates with the former, and from there into the housing-external convective radiator structure/arrangement.

Relevantly, the various structures and components that make up the thermal mitigation system will be designed and dimensioned such as to prevent the inside volume of the enclosure and in particular the heat generating electronic and electric components of the antenna signal generators housed on the rotatable PCB from reaching steady-state operating temperatures that negatively affect or over time degrade performance of the electric and electronic components, typically around environmental temperature levels of +55° C. Selection of suitable components/structures of the thermal mitigation system, and optimisation of their size and shape, aims to create an as small as possible module size and footprint, whilst maintaining a steady operating temperature within the housing that reflects the specification (recommended maximum operating temperatures) of the internal electronic components of the telecommunications equipment.

Embodiments and structures for the thermal mitigation system will be described below.

The thermal load mitigation system may optionally also provide means for (iv) convective heat removal from some of the lower-heat generating components into the housing through a finned heat sink thermally conductively coupled to these heat sources, and preferably also to the rotatable heat sink so that heat can also be directed into the latter.

Although air is usually viewed as an insulator when planning heat transfer management, the thermal mitigation system in accordance with the present invention makes use of an ‘air gap’ in the heat transmission path inside the housing between the rotatable heatsink and the non-rotating heat sink component collocated within the housing, as there is a risk that any low-viscosity thermal interface material (fluid) disposed between the rotatable and the co-operating stationary heat sink bodies could seize at low temperature or degrade over time with the fluctuations in temperature expected during normal operation.

In order to provide for an as efficient as possible thermal conductance path between the enclosure-internal rotatable heat sink and the enclosure-internal stationary heat sink, which comprises air gaps, whilst maintaining free relative rotational capability between the two heat sink components, it is advantageous for both sink components to comprise a plurality of concentric annular fins that interleave with each other in a manner that an as small as possible but rotation-enabling air gap is maintained between facing surfaces of the fins. Thermal expansion and contraction of the fins in the temperature operating range of the modem, typically in external environmental conditions of between −40° C. to +60° C., needs to be catered for. Preferably, the housing-internal, rotatable heat sink is made of the same metal alloy material as the co-operating housing-internal, stationary heat sink.

The width of the air gap between the fins of the rotatable and stationary enclosure-internal heat sink structures will be selected based on heat transfer efficiency, manufacturing machining tolerances as well as expected maximum and minimum operating temperatures within the housing, to cater for thermal expansion/contraction of the interacting components. Based on computer modelling, a possible iteration uses a gap of 1.0 to 1.5 mm between the surfaces of the concentric fins, which has been chosen for ease of manufacturing to the required tolerances. Using suitable aluminium alloys for the heat sink structures described, modelling suggests that this can achieve a 10° C. temperature differential between the housing-internal heat sink and the housing-external heat radiator at an ambient temperature of +55° C. in steady state operation of an outdoor 5G-enabled telecommunications module.

In an advantageous embodiment, the housing-external convective radiator structure/arrangement is provided on/at a closure member for an access opening of the housing. In this manner, the same module housing may be used for PCBs carrying different types of heat generating components, and therefore different overall heat generation ratings can be catered for, whereby radiator structures optimised as regards a specific one or more of heat removal ratings can then be provided/mounted to the closure member.

A particularly advantageous module format is one consisting of a preferably cylindrical housing having either an integral but preferably separate bottom closure cap, and in which the closure member is a cap or top closure member of the main cylindrical housing part which in operation is arranged in a generally vertical orientation.

In a preferred form, both the non-rotatable, housing-internal heat sink and the enclosure-external convective heat radiator are integrally formed with the closure member out of a suitable metal of high thermal conductivity, eg an aluminium alloy, thereby avoiding any interfaces in the heat conduction path between inside and outside of the enclosure (modem housing) comprising materials that conduct heat more poorly than an integral/unitary metallic body. It is possible though to manufacture the different heat transfer structures separately and assemble these together.

Advantageously, the enclosure-external convective heat radiator comprises a plurality of pin-like radiation elements in mutually spaced apart array configuration, such as concentric rows of upstanding pin elements spaced apart to maintain a predetermined small air gap with respect to each other, preferably no less than 0.5 mm, and more preferably around 1.0 to 2.5 mm. A different array configuration of the plurality of pins can of course also be selected, e.g. an orthogonal square array of interspaced pin rows.

Metallic pin elements that stand proud from and are integral with a base plate of the enclosure closure member, and spacing the plurality of pins appropriately, are selected to facilitate conductive but primarily convective heat transfer into the ambient air surrounding the housing (herein after also referred to as an enclosure).

The pins may be cylindrical, square or of other cross-sectional shape, and may not necessarily all have the same length (above the base plate), thereby creating a non-uniform temperature field across the entirety of pins which is conducive to thermally-induced air flow about the radiator.

The housing-external radiator employs a pin design because it is believed to be an effective form of heat transfer structure that does not require (additional) air flow or convection assisting structures or devices.

In accordance with other embodiments, fin-like structures instead of pin-like elements may be used in the convective radiator. The fins can have a variety of shapes and can be arranged in various configurations. The optimal combination of shapes and arrangements can be determined using software-based heat transfer optimisation models. In this context, although developed for a different purpose (heat removal from high-power LED lighting applications), finned heat radiator structures (heat sink) as proposed in the following documents could be used: ‘Optimum design of a radial heat sink with a fin-height profile for high-power LED lighting applications’, Daesok Jang, Se-Jin Yook, Kwa-Soo Lee, Applied Energy 116 (2014) p. 260-268, and ‘Optimization of a chimney design for cooling efficiency of a radial heat sink in a LED downlight’, Seung-Jae Park, Daesok Jang, Se-Jin Yook, Kwa-Soo Lee, Energy Conversion and Management 114 (2016) p. 180-187.

The fin-like structures may advantageously comprise a series of radially extending fins. In one form, the fins are all the same width and thickness and are arranged in concentric rings around the radiator. Each ring can have fins of a different height. The rings can increase in height towards the centre of the radiator to produce the appearance of a frustoconical shaped outer profile. Alternatively, the rings can decrease in height towards the centre of the radiator to form the appearance of a frustoconical shaped depression in the radiator. Heat transfer and heat dispersion from the heatsink can be optimised by changing the height of each ring or by changing the height of individual fins.

In another form, the fins are all the same height and comprise fins that extend over most of the radius of the radiator interspersed between fins that extend less than the radial extent of the first mentioned fins, eg ¼ to ⅓ or ½ of the radius of the radiator structure.

From a practical perspective, noting the intended environment of use of the modem in outdoor conditions, the housing-external heat radiator structure will be devised to prevent water from pooling, trapping of debris, take account of solar loading, amongst others.

An additional concept foresees the use of a chimney or funnel structure at the housing on top of the housing-external heat radiation structure. The chimney may be fitted on top of the radiator to further improve cooling efficiency. The chimney may comprise a pipe section with a flanged end, such that when the chimney is assembled onto the radiator the flanged end abuts a top surface of the fins.

Using a radiator design with a plurality of radial fins (instead of pins) has been investigated using thermal simulation tools. Use of a topping funnel structure allows for optimised convection airflow over the heat exchanger fins, i.e. the creation of an updraught of air entering radially into the zone of heat exchanger fins and discharging upwardly through the funnel. All else being equal, the presence of such funnel structure when used with a radiating heat sink having radiator fins, will in most cases improve overall cooling efficiency by a noticeable % degree as compared with modem embodiments devoid of such funnel structure. An advantage of the chimney/funnel structure is that it can serve to reduce the total amount of material required to manufacture the radiator component without compromising heat transfer capacity into the surrounding air. The chimney part can be moulded from the same plastic material as the main housing part and will also act as a solar shield and provide the heat sink structure with some protection from foreign materials.

In a preferred embodiment, the thermal mitigation system uses at least one heat pipe for assisting with the conductive heat transfer away from the high heat generating IC components on the telecommunications equipment PCB. For such purpose, the heat pipe(s) is (are) directly thermally coupled to the components (but electrically isolated from these) or indirectly via a heat spreader body mounted to the PCB, and the rotatable heat sink. The heat spreader body could have fins for convective heat transfer, as noted above, but in one embodiment will not incorporate features that promote convective heat transfer from the heat spreader into the housing, and will rather be devised to primarily remove the heat load received through heat conduction into the rotatable heat sink.

Preferably, alcohol-filled copper heat pipes are used, specified to meet a minimum operating temperature requirement of −40° C. without freezing.

Noting that liquid-filled heat pipes are most effective when drawing heat upward from a heat source, in a most preferred embodiment of the modem, the external heat radiator (and the co-working housing internal rotatable and non-rotatable heat sinks) will be located, in use of the modem, at the top of the modem unit, and the heat pipe(s) and PCB-mounted, associated heat spreader body will extend primarily in a vertical orientation.

In another aspect, the present invention provides the components of a thermal mitigation system for use with a PCB-based antenna, as described above, either in a preassembled format with the PCB antenna, or as a kit for incorporation into a stationary RF-transmission module/modem/router for outdoor use.

In accordance with a further embodiment, a mounting arrangement can be provided at the housing, for mounting the fixed wireless modem/router module to a vertical pole, the mounting arrangement comprising a first clamping unit that includes a section of the modem/router module and a first clamping element extending from the modem/router module section, and a second clamping element, with the first and second clamping elements being configured to be connected together in clamping engagement with the pole, wherein in use the modem/router module can be releasably secured to a top section of the pole by clamping the first and second clamping elements to the pole, with the modem/router module being positioned in relation to the pole such that signals to and from the modem/router module are unobstructed by the pole or the mounting arrangement through 360 degrees.

Further features and aspects of the invention will become clearer from the following description of two, non-limiting embodiments of the invention provided with reference to the accompanying drawings. It will be understood that features illustrated in the various embodiments may be interchanged where such are functionally equivalent.

### BRIEF DESCRIPTION OF THE DRAWINGS

FIG. 1 is a schematic top perspective view of the primary components of a thermal mitigation system for use within a housing of a wireless fixed transmission/reception module, in accordance with a first embodiment of the invention;

FIG. 2 is a view similar to FIG. 1 but from a bottom perspective viewpoint;

FIG. 3 is a transparent schematic illustration of the primary components of a thermal mitigation system of FIG. 1 as-received within the modem housing, but omitting the finned heat sink block illustrated in FIG. 1;

FIG. 4 is a side section elevation of the telecommunications module shown in the previous figures;

FIG. 5 is a schematic top perspective view of the primary components of a thermal mitigation system for use within a housing of a wireless fixed transmission/reception module, in accordance with a second embodiment of the invention;

FIG. 6 is a view similar to FIG. 5 but from a bottom perspective viewpoint;

FIG. 7 is a transparent schematic illustration of the primary components of a thermal mitigation system of FIG. 5 as-received within the modem housing, but omitting the heat sink block associated with heat pipes of the thermal conduction arrangement illustrated in FIG. 5;

FIG. 8 is a side section elevation of the modem shown in FIGS. 5 to 7 illustrating in particular the PCB rotation arrangement;

FIGS. 9A to 9C are top perspective views of respective convective heat transfer structures (radiators) illustrating different arrangements of fins, in accordance with an aspect of the invention;

FIGS. 10A to 10C are heat transfer plots from a computer simulation corresponding to the respective arrangements shown in FIGS. 9A to 9C, where the left-hand set of images are two-dimensional plots along a cross-section of the convective heat transfer structures and the right-hand set of images are perspective views of three dimensional plots of a segment of the heat transfer radiation structure;

FIG. 11 is a top perspective view of a chimney positioned on top of the heat transfer/radiation structure shown in FIG. 9A; and

FIG. 12 is a bottom rear perspective view of a mounting arrangement for mounting the modem of FIG. 5 on a pole, in accordance with an aspect of the invention.

### DESCRIPTION OF PREFERRED EMBODIMENT

The accompanying drawings illustrate schematically in various views two embodiments of a 5G/4G LTE reverse-compatible, outdoor-mountable, fixed wireless modem/router module 10, 100 with respective thermal mitigation systems 30, 130.

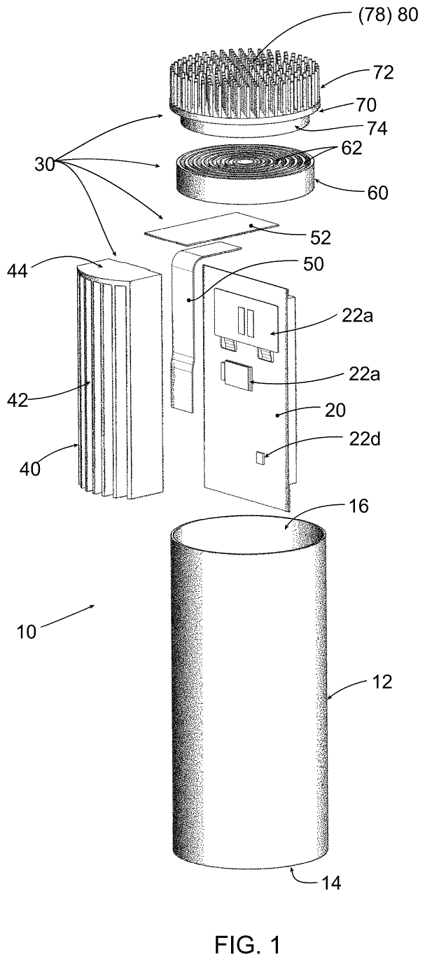

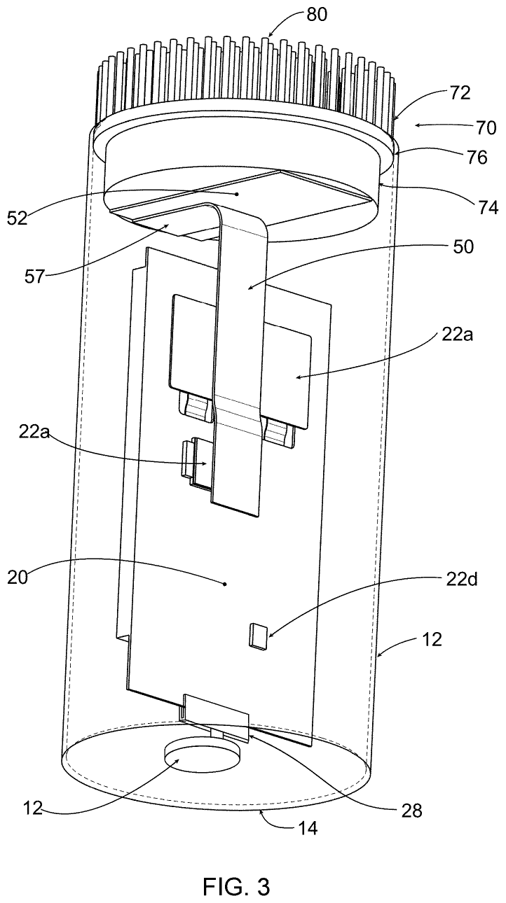

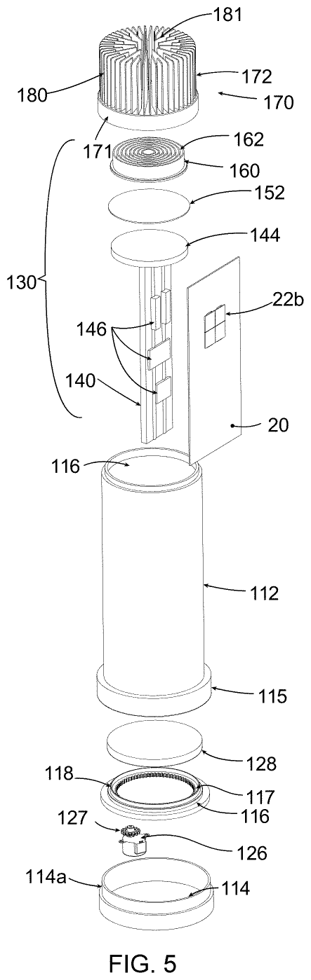

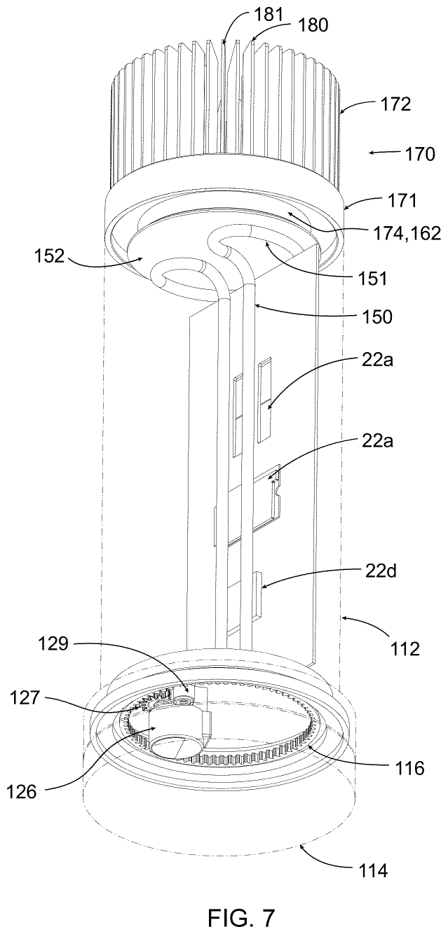

But for differences specifically mentioned below, the embodiments illustrated in FIGS. 1 to 4 and FIGS. 5 to 8, respectively, have a degree of commonality. Consequently, functionally equivalent features are present throughout FIGS. 1 to 8, wherein the embodiment of FIGS. 1 to 4 use reference numbers in the 1-99 range and the embodiment in FIGS. 5 to 8 use similar reference numbers but in the 100 to 199 range. Components that differ in their layout/function in transferring thermal loads, will also be addressed below.

Turning then first to FIGS. 1 to 4. Module 10 comprises (i.e. includes or has) a cylindrical main housing part 12 closed integrally, or otherwise closed sealingly using a separate closure part, at one (bottom) end 14 thereof. Open (top) end 16 is internally threaded and closed by a top closure element 70 with integrated heat transfer/radiation structures as will be described below.

Housing part 12 is made of a suitable, environmentally-hardened, RF-transparent polymer, such as ASA or PC with an ideally as close to 0 dielectric loss factor, and which in essence is not heated by RF-radiation emanating from within the module.

Module 10 will be supported/fastened in use to an outdoor structure like a building wall or a post using non-illustrated mechanical fasteners in a vertically upright position, with the closed end 14 oriented towards the ground. The outside of housing part 12 may also have appropriately formed mounting structures.

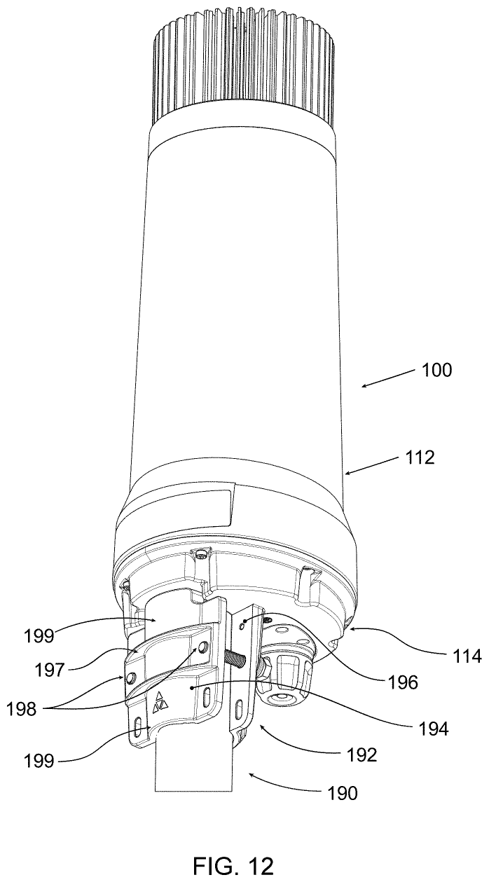

FIG. 12 illustrates one clamping mounting arrangement that is partially integrally formed with a bottom closure cap of the housing and by way of which the modem 10 or 100 can be mounted on top of a pole. This will be described briefly below.

The wall thickness and additional rigidity imparting structures like internal or external ribs or webs have been omitted from housing 12 for clarity purposes. The cylindrical main housing part 12 could also incorporate external heat radiation fins, as is otherwise known from other electrical devices with heat sources arranged within a sealed-off, so-called environmentally hardened casing, but this is less preferably as such structures can interfere with the radiation pattern of the antenna elements located within the modem 10.

Modem unit 10 is configured specifically as a cellular outdoor modem with both omni-directional antenna elements and directional antenna elements that may require sporadic spatial re-orientation. A typical (but not limiting) size for such modem would be 100 to 200 mm in diameter with a height of 350 to 450 mm.

Modem 10 uses PCB antenna technology which is known to the skilled person in fixed telecommunications equipment. A single, main PCB carrier 20 supports several PCBAs and other components like transformers, including a 5G mmWave modem chip 22a, mmWave active antenna modules 22b, sub-6 GHz antenna elements 22c, an ethernet controller chip 22d, high speed transceiver(s), device power management circuitry, etc. In the figures, these components are only illustrated schematically.

Typically, the RF antenna elements 22b and 22c are disposed on one face of the PCB 20 to radiate in a direction Normal to and away from a main plane of the PCB 20 (i.e. not through the PCB) while driving and power circuitry components (such as modem chip set(s) 22a, 22d, etc.) are mounted on the opposite face of PCB 20. The skilled person in telecommunications equipment, particularly fixed wireless equipment for use in 4G LTE and 5G, will appreciate however that there are a variety of suitable electronic components, antenna modules and driving circuitry components and arrangements that can be chosen for incorporation into a single PCB and various PCBA configurations.

Noting that the directional antenna modules 22a are mounted to the PCB 20 to essentially receive and radiated RF-signals from one face (or plane) of the sheet-like PCB only, and that signals transmitted and received in the mmWave frequency bandwidth ‘bounce’ a lot directionally, PCB 20 is received and mounted with its principal plane perpendicular to the horizontal reference ground and for stepwise (or non-stepwise) rotation about a vertical central axis within housing 12 thereby to enable selective (re-)orientation of the directional antennas with one degree of rotational freedom.

There are various ways of specifically implementing a suitable support arrangement of the PCB 20 within housing 12 that allows the PCB 20 to be rotated (and thus the antennas 22b re-oriented) and various drive arrangements to effect such rotational re-alignment can be chosen.

In the embodiment of FIGS. 1 to 4, the PCB support arrangement and rotational drive are illustrated merely schematically. In that embodiment, a rotary actuator or motor 26 is received within housing 12 and secured to the housing bottom 14. The motor 26 is arranged to output torque and rotationally drive an axle of support fork 28 onto which PCB 20 is removably clamped.

In contrast, the embodiment of FIGS. 5 to 8 illustrates in greater detail one practical implementation of the PCB support arrangement with rotational drive. Modem 100 there comprises a cylindrical (tubular) housing part 120, with an open top 116, closed in sealing fashion by upper cap member 170. The lower open end of cylindrical housing part 120 is cylindrically flared to define a collar 115 which is adapted to receive a closing bottom cap 114, preferably incorporating a not-illustrated sealing ring or packing. Cap 114 can (but need not) be made from a metallic material and as illustrated in FIG. 12 may incorporate additional features to enable fastening of module 100 in an upright orientation to a support structure outdoors. Cap 114 has a tubular terminal rim portion 114a that provides a matching sealing surface that cooperates with and seats within collar portion 115 of housing 112, and is secured using appropriate permanent (or non-permanent) fixing means, including adhesive bonding.

An annular bearing flange 116 with a ring of radially-inward directed teeth 117 provides an annular gear element that is sandwiched between the upper terminal rim portion 114a of bottom cap 114 and a facing ledge or step which collar 115 forms with housing 120, such that bearing flange 116 is secured against movement (rotation and axial). Additional measures can be provided to secure annular gear element/bearing flange 116 against rotation, such as glue, index features, etc. Annular gear element 116 could be made of metal but equally of a suitable polymer material, such as glass reinforced polyester or the like, having high impact resistance yet sufficient E-modulus to provide form stable teeth 117 into which comb a pinion 127 driven by the output axle of electric stepper motor 126.

Motor 126, which may be a stepper motor, is fixed against movement in a suitable mounting structure 129 moulded integrally on the underside of a circular support plate 128 that has an annular skirt 125 on its bottom facing side.

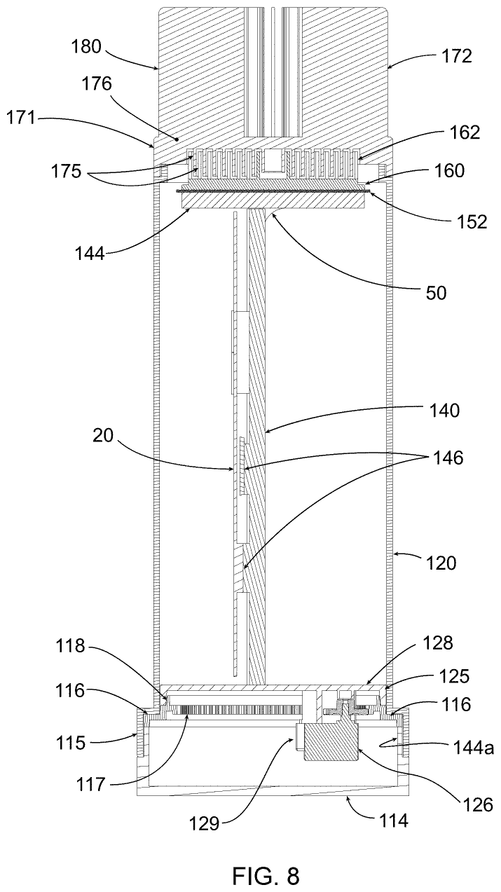

Circular support plate 128 can be made from an electrically insulating metal but is preferably made from an electrically insulating, low friction polymer material. As best seen in FIG. 8, the bottom-facing annular skirt 125 of support plate 128 locates in an annular space defined between the inner peripheral face of cylindrical housing 120 and an upper ring portion 118 of annular gear element 116 in such manner that support plate 128 remains free to rotate about the central axis defined by housing 120 with as little play as possible. That is, the geometries of the various components that interact with one another are chosen such as to prevent rotational jamming of the support plate 128 when supported at upper terminal ring bearing portion 118 of bearing flange/gear element 116 and at expected operational temperatures within module 100.

It will be immediately appreciated that the chosen arrangement is such that actuation of motor 126, which rotates with circular support plate 128, causes its driven pinion 127 to rotationally move support plate 128 through its interaction with the stationary gear ring 116.

Finally, and again with reference to FIG. 8 but also FIG. 5, it will be noted that a metallic block 140, which forms part of the thermal mitigation system 130 as will be explained below, is secured to PCB 20. That is, PCB 20 is carried at metallic block 140 which in turn is mounted to the top face of support plate 128 for rotation therewith, eg glued or otherwise shape-fittingly carried. Consequently, rotation of circular plate 128 will cause the PCB 20 to re-orient its main plane about the vertical rotation axis, as a function of the geared engagement between motor 126 and stationary gear ring 116.

The skilled person will appreciate that there are various ways of providing power supply not only to the drives 26, 126 that rotate PCB 20, but, more relevantly, to the PCBAs and all electronic components required for signal generation and transmission. Equally not shown, because these components are well known in the fixed wireless modem design and manufacturing industry, are a non-rotating PCBA for external interface ports of the modem, typically carried at the bottom 14 (or closure 114) of housing 12, 112, with internal flexible power supply and controller cabling trees and management equipment.

In order to detect and know by how much the rotatable internal PCB 20 with its otherwise positionally fixed antenna modules 22b needs to be rotated such that the modem unit is appropriately ‘tuned’ for optimal transceiver performance, the PCBAs incorporate programmed or programmable processors for measuring signal strength from different directions as received by directional antenna elements 22b. The sensor signals are processed by a dedicated controller which is operationally associated with the rotational actuator or motor 26, 126 which is mechanically coupled to PCB 20, thereby enabling selective angular re-orientation of the antenna 22b to point towards the direction with the best measured signal source. The PCBAs can also be fitted with suitable circuitry to monitor signal strength and re-measure if there is a significant change in signal strength or quality, for example if the original signal source has been blocked by something in the surrounding environment. This means that the moveable PCB 20 of the modem 10, 100 is expected to remain stationary during most of its operating life with occasional periods of movement and measurement.

This also means that the design of the thermal mitigation system (or arrangement) 30, 130 needs to be considered when refining the design and placement of the antennas 22b to ensure that the metallic heat management components of system 30, 130 do not prevent the antennas 22b from performing efficiently at the desired frequencies, yet allow the heat generated by the various components of the modem unit 10, 110 such as the mmWave modem chip(s) 22a, to be effectively transferred to an internal heat sink and from there to an external heat radiator which dumps thermal load into the surrounding environment. That is, the antenna elements 22b need to be located on the PCB 20 such that the effective beam of the antenna radiation patterns should not intersect with heat sink and conduction arrangements.

Similarly, as noted above, wireless transmission modems with reverse compatibility which cater for various transmission standards leads to PCBA designs with a large number of components consuming up to 10 W each and creating hot spots on the PCB 20 which produce excess heat which needs to be conducted away from the PCBAs and heat-sensitive ICs, to enable the device to operate effectively up to a maximum (housing inside) operating temperature of +55° C.

Components required to drive 5G antennas have much larger transient power output levels that those used of other (e.g. 3G) antennas, and when taking account of an assumed duty cycle of TX to RX of 15%, this would mean a typical power output of a mmWave modem chip of approx. 18 W. Conventional thermal mitigation strategies and arrangements will not do the ‘cooling job’ appropriately.

Thermal mitigation system 30, 130 employs different components and heat transfer mechanisms to remove heat generated by various electric and electronic components of a PCB antenna arrangement, in particular mmWave antenna signal generation equipment received on the PCB, which is mounted within the water and dust tight housing 12, 112 to allow rotational re-orientation of the directional antenna components, to an internal heat sink within the sealed housing (enclosure), and transfer of heat from the internal heatsink to an external, non-rotating heat transfer radiator.

In the following will be described the various components/constituents of a prototype thermal mitigation system 30 of the invention's embodiment illustrated in FIGS. 1 to 4, devised for a mmWave modem unit of the type described above, in which all components of the PCBAs have a power consumption of around 39 W which, but for the power radiated by the antenna elements (including 22b), is essentially converted into a thermal load which needs to be dissipated away from the temperature-sensitive electronic components 22a, 22c, 22d of the PCBAs within the housing 12 into its ambient surroundings.

Subsequently, a furthermore elaborate embodiment of a modem 100 with modified thermal load mitigation system 130 will be described with reference to FIGS. 5 to 8, noting that the principles employed in both systems 30, 130 are the same but for one notable change. Functionally equivalent structures are denoted by same reference numerals but in the one hundred range as regards FIGS. 5 to 8 instead of reference numbers in the below one hundred range of FIGS. 1 to 4.

Having reference to the embodiment of FIGS. 1 to 4, the thermal mitigation system 30 essentially is comprised of a finned heat sink spreader 40, two heat pipes 50, 52, a rotatable upper heat spreader (or sink) 60 mounted against displacement on the top edge of and extending perpendicular to PCB 20, and a stationary heat sink and radiator arrangement 72, 74 thermally coupled to the rotatable upper heat spreader 60, for receiving the thermal load provided by the upper heat spreader 60 for convective and radiative disposal outside of housing 12, as described in more detail below.

In a preferred embodiment, the stationary heat sink and radiator arrangement 72, 74 will be manufactured as a single integrally formed component and will particularly advantageously be integrated into top closure element or cap 70 which is used to sealingly close the open top 16 of housing 12. This minimises component count and provides a more efficient heat transfer arrangement, although it is possible and feasible to provide three metallic components that are butted and fastened to each other without air gaps that are detrimental to heat conduction.

Top closure element 70 is manufactured by casting or other suitable metallurgical process (including additive manufacturing techniques) from an aluminium alloy or other metal with good thermal conduction properties and heat transfer coefficient. Top closure 70 is designed with (i) an adequate mass for temporarily storing substantial amounts of heat as continuously generated from heat sources (e.g. 22a) mounted to PCB 20 received within housing 12 as noted above, (ii) a heat transfer/radiation structure 72 which locates outside housing 12 when closure element 70 is mounted to close open top 16 of housing 12, optimised for small air gap conductive, convective and radiant transfer of heat into the surrounding environment of module 10, within an environmental operating range of typically −40° C. to +55° C., for example, and (iii) a stationary heat sink/transfer structure 74 which locates inside the housing 12 when top closure 70 is mounted to housing 12, optimised for small air gap conductive reception of heat from the operationally associated and thermally cooperating rotatable upper heat spreader 60 (as described in more detail below) located within housing 12.

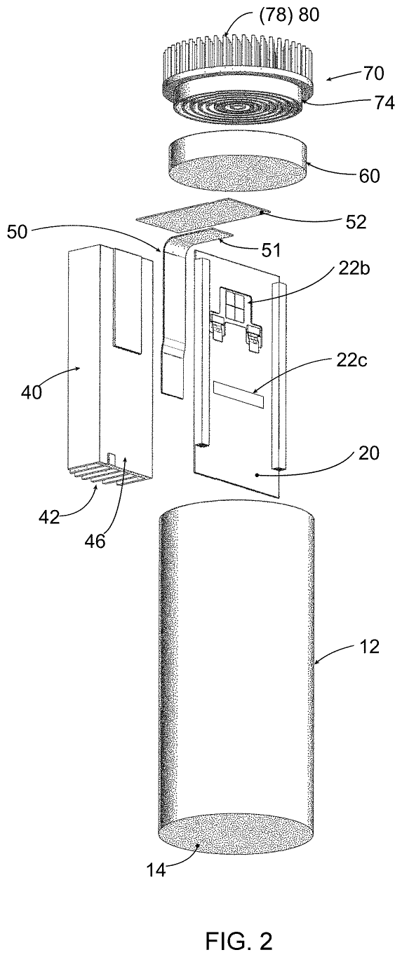

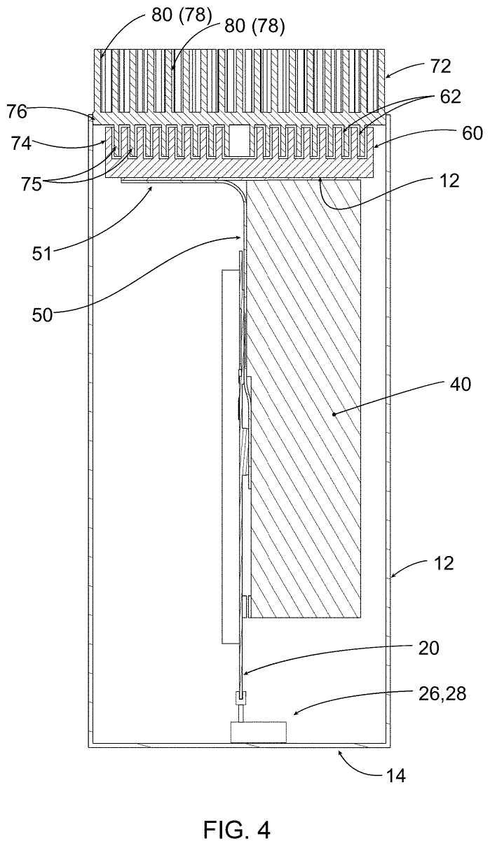

More particularly, as seen in FIGS. 2 and 4, top closure 70 has an essentially plate-like circular base 76 of suitable thickness, with a peripheral tread, and which serves to substantially hermetically seal the inside of housing 12 against water and dust ingress when threaded into open end 16 of housing 12. A separate seal element may assist in such sealing, and a different way of sealingly securing top cover 70 to housing 12 may be chosen.

Integrally with circular base 76, exterior heat transfer/radiation structure 72 consists of concentrically arranged annular rows 78 of radiator pins 80 of suitable number, diameter, height and small spacing from each other for adequate heat transfer/radiation into the surrounding air of the heat load it receives through heat conduction over any given time period from the interior heat sink/transfer structure 74 of top closure 70. A spacing of 1.5 mm between individual pins appears to create a structure of discrete metallic components with which convective heat transfer into the surrounding air is within desired parameters.

Integrally with circular base 76, interior heat sink/transfer structure 74 consists of a number of concentrically arranged annular fins 75 (as best seen in FIGS. 2 and 4) of suitable number, radial thickness, height and spacing from each other for receiving, primarily through small air gap heat transfer, the heat load from complementarily-shaped and arranged annular fins 62 that make up a substantial height of the cylindrically-squat shaped rotatable heat spreader structure 60 located inside housing 12. To that end it will be appreciated that the number of annular concentric fins 62 of rotatable heat spreader structure 60 and annular concentric fins 75 of stationary heat spreader structure 74 as well as their radial thickness and radial spacing from each other is chosen such that the respective annular fins 62, 75 interleave with a sufficiently small air gap spacing, which beyond manufacturing tolerances, also takes account of thermal expansion characteristics of the respective materials of the cooperating inner heat sink structure 74 and rotatable heat spreader 60. Whilst the latter two components 60 and 74 (and therefore the top closure member 70) need not be made from the same heat conductive metal alloy, it is currently preferred for both to be made from a suitable cast aluminium alloy.

As can be seen in particular in FIGS. 1 and 2, the finned heat sink 40 is a unitary (preferably cast) metal (e.g. aluminium alloy) body comprised of seven (but could be more) parallel radiating fins 42 that terminate in a common top wall portion 44 extending traverse to the fins 42 as well as to the common base plate portion 46. The latter has an area or foot print that is somewhat smaller than the facing area of PCB 20, and which is intended to be secured to the rear of PCB 20 over many/most of the heat generating electronic and electric components of the modem 10, on a side opposite the radiating antennas 22b, with a thermal pad or paste ensuring electrical isolation but good heat conductance into the finned spreader 40. Size, mass and design of finned heat sink 40 allows it to perform a heat load ‘spreading’ function in that it takes-up heat from heat-generating electronic components mounted to the PCB 20 (as outlined above) and ‘diffuse’ it for better cooling efficiency (i.e. heat removal from localised warm spots on PCB 20).

The rear heat spreader 40 with parallel fins convectively transfers some of the heat received into the sealed housing 12 cavity (via its fins 42) and minimises hot spots at the locations of individual components on the PCBAs. Simulations have showed that the rear heat spreader 40 needs to have a much smaller width than the internal diameter of hosing 12 to allow adequate convective airflow within housing 12 to transfer some of the thermal load generated.

The rear heat spreader 40 is furthermore also thermally coupled through a central portion of its base plate portion 46 with, and appropriately releasably secured to, a first, generally upright orientated, flat sectioned heat pipe 50 whose upper terminal end 51 is bent at 90° to extend about parallel with the top end wall portion 44 of heat spreader 40.

A second, generally horizontally orientated, flat-sectioned heat pipe 52 having a greater width than heat pipe 40 is thermally coupled with and appropriately releasably secured to the outside of common top wall portion 44 of rear heat spreader 40, to remove heat from spreader 40 through heat conduction into horizontal heat pipe 52

The second, horizontally extending heat pipe 52 has a width that is greater than the first heat pipe 50 and about the same as the width of finned rear heat spreader 40. It is releasably secured to the bent portion 51 of first heat pipe 50 on a bottom-oriented face thereof, and on its top oriented face to the underside of the essentially squat-cylindrically shaped upper heat spreader 60.

The upright heat pipe 50 is thermally coupled and releasably secured to the rear side/face of PCB 20 to lie above the more energy-consuming, and therefore hotter, heat generating electronic components of the PCBA (in particular the mmWave modem chip 22a). Relevantly, whilst in thermal contact with and secured to the PCB 20, vertical heat pipe 50 (but also horizontal heat pipe 52) is electrically isolated from the PCB and the PCBAs.

The heat pipes 50, 52 are custom-developed alcohol-filled, formed copper heat pipes to conduct heat away from the hot spots on the PCBAs. Alcohol-filled heat pipes are specified to meet the minimum operating temperature requirement of −40° C. without freezing.

It has been found that such heat pipes 50, 52 are most effective when drawing heat upward from a heat source. Consequently, from a heat transfer management perspective, the stationary heat sink and radiator arrangement 72, 74 is advantageously placed at the top of the modem housing 12, and preferentially made integrally with closure cap 70, whilst side-wise located external radiator structures like known in the prior art, are not believed to be at all viable or at least less viable for removing the heat which in particular is generated by mmWave signal generators received within small format modem housings, as is the case here.

As has been noted, cylindrically-squat shaped upper heat spreader 60 is designed to have freedom of rotation relative to and within housing 12 and the co-operating stationary inner heat sink/transfer structure 74 of the combined heat sink and radiator arrangement provided at the top of housing 12. Its upward facing side is cast with concentric annular fins 62 that mesh with the set of annular fins 75 on the downward-facing side of the heat sink 74. This allows for a high surface area, which increases heat transfer, and enables rotation around the central axis with a narrow air gap between the moving and stationary parts.

Relevantly, as noted, upper heat spreader 60 is secured against rotation to the PCB 20. This can be effected using mounting clamps or other mechanical (or adhesive) fasteners, not shown in the figures.

Although air is usually viewed as an insulator when planning heat management, this design makes use of an air gap because there is a risk that any low-viscosity thermal interface material (fluid) could seize at low temperature or degrade over time with the fluctuations in temperature expected during normal operation. The width of the air gap can be selected based on the required heat transfer efficiency and manufacturing machining tolerances. A possible iteration uses a 1.5 mm gap between the surfaces of the concentric fins, which has been chosen for ease of manufacturing to the required tolerances. This leads to a 10 degree difference in temperature between the upper heat spreader and external heat sink at an ambient temperature of +55 degrees Celsius. If a 0.5 mm gap were used the resulting temperature difference would be 5 degrees.

The heat spreaders and heat sinks 40, 60, 72/74 can be made from die-cast aluminium. The external surfaces of the heat sinks could be coated with a corrosion-resistant finish such as Dacromet, which does not impact the thermal properties of the underlying material.

Turning then to the modem embodiment illustrated in FIGS. 5 to 8, it will be seen that there are many commonalities in the thermal mitigation system 130 when compared to that of the first embodiment, and therefore the following description will primarily focus on constructional and/or lay-out differences.

The stationary upper heat sink and radiator arrangement 172, 174 is in this embodiment also manufactured as a single integrally formed component and particularly advantageously unitary with top closure element or cap 170 which is used to sealingly close the open top 116 of housing 112. The cap 170 here comprises a housing-facing annular skirt 171 that is internally threaded for cooperating with an externally threaded terminal annular top rim 113 of housing 112 to seal-off module 100. However, instead of comprising a plurality of heat radiating pins 80, the housing-external radiator structure 172 consists of a plurality of radially extending upright fins 180 that converge towards the longitudinal axis of housing 112. Interleaving with fins 180 that have a radial extension such as to terminate closer to a central cylindrical void defined by the radially inner ends of the fins 180, are a plurality of radially shorter fins to maximise fin density when packed into a radially converging convective heat radiating array or structure.

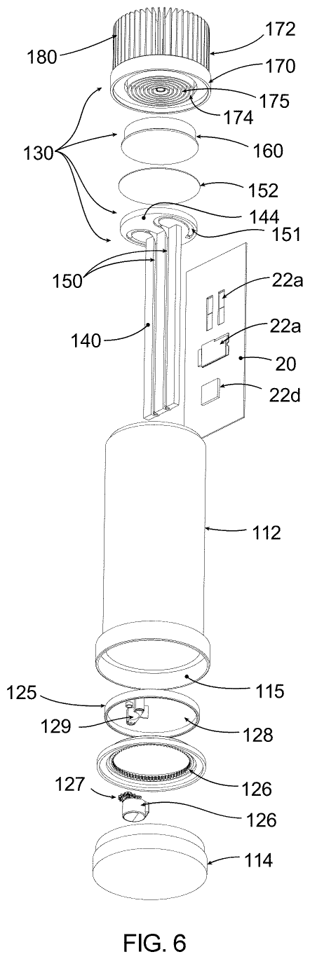

As may be seen from FIGS. 6, 7 and 8, the upper stationary heat sink structure 174 unitary with upper closure cap 170 is here also comprised of concentric annular fins 172 that face into the inside of housing 112, are integral with central body part 176 of cap 170 and interleave with the plurality of concentric annular fins 162 of the rotatable upper heat spreader body 160. For additional details, refer to the description of these heat transfer components provided with reference to the first module embodiment.

It will be further seen that rather than having a finned heat spreader block 40 as illustrated in FIGS. 1 to 4, in the presently described embodiment the metallic heat spreader block 140 has no fins and instead has two parallel channels running along the height of block 140 and in which are received circular cross-section heat pipes 150 that are otherwise, from a heat transport perspective, similar in function to the main heat pipe 50 described previously. Suitable thermal putty ensures air-gap free fitting of heat pipes 150 in the receiving channels of heat spreader block 140.

It will also be noted that a separate metallic circular top plate 144 is soldered or otherwise secured for gap-free thermal conduction to the top terminal face of block 140, rather than being made integral with the latter, as was the case with the finned heat spreader block 40. Top plate 144 is provided with semi-circular channels which accommodate the horizontally bent upper terminal ends 151 of heat pipes 150 in similar fashion as previously described. That is, in comparing the heat transfer systems 30 and 130, with the exception of providing for convective heat transfer via fins into the inside of housing 112, heat spreader block 140 together with top plate 144 perform the same heat conduction functionality towards the rotatable upper heat spreader 160 as block 40 but with less convective heat radiation surface area present within the housing 112.

The upper second heat transfer pipe 52 of the module embodiment of FIGS. 1 to 4 is omitted altogether, and instead a thermal pad 152 is fixed in abutting contact with the upper face of top plate 144 and the bottom-facing surface of upper heat spreader 160. The three components could be glued to each other but are preferably fastened to each other in a manner that allows these components to be taken apart, but ensures a rigid connection of upper heat spreader 160, top plate 144 and heat spreader block 140. As was mentioned previously, given that heat spreader block 140 is secured for rotation with circular support plate 128 at the bottom of housing 112, this connection methodology enables upper heat spreader to rotate with block 140 and thus with PCB 20.

Thermal pad 152 is devised as a surge barrier, ie a member to electrically isolate the rotatable heat transfer components of system 130 from the upper, fixed heat sink body 174.

Finally, and best seen by comparing FIGS. 5, 7 and 8, rather than providing for essentially full contact between the PCB-facing side of heat spreader block 140 with all heat generating components of the telecommunications system carried on/at PCB 20, discrete metallic pads 146 are shaped and located to come into heat conductive contact with the particularly ‘hot running’ IC and chips carried at the PCB 20, thereby to focus heat removal through conduction from these components into the central spreader block 140. It is believed that these pads 146 in conjunction with block 140 improve overall heat removal efficiency towards the external convective heat radiating structure 172 at the top of the module 100, through the various intermediary components 150, 144, 152, 160 and 174 of the heat transfer system 130.

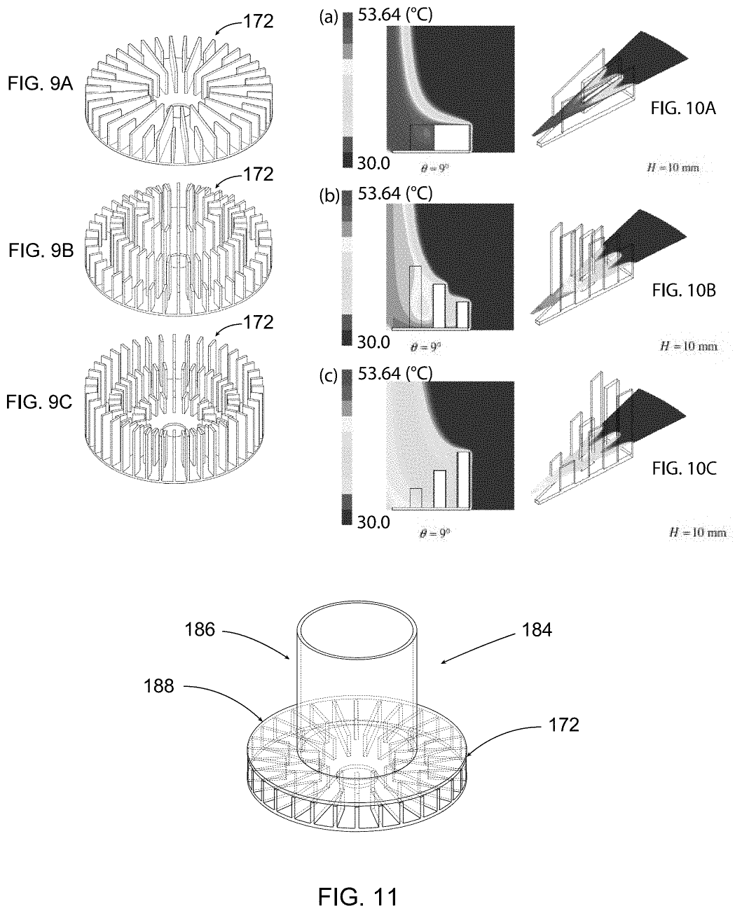

FIGS. 9A to 9C show different examples of fin arrangements that can be incorporated into the heat transfer/radiation structure 172 as previously described. Similar to the arrangement shown in FIGS. 5 to 8, but in a lesser density of packing, in the example shown in FIG. 9A, the fins are all the same thickness and height. The fins comprise a set of long fins, that extend for a substantial part of the radius of the heat transfer/radiation structure, interspersed between smaller fins that extend about ¼ to ⅓ radius of the heat transfer/radiation structure.

In the examples shown in FIGS. 9B and 9C, the fins are all the same thickness and width and are arranged in concentric rings around the heat transfer/radiation structure. In FIG. 9B, the rings increase in height towards the centre of the heat transfer/radiation structure to form the appearance of a frustoconical shaped outer profile. In FIG. 9C the rings decrease in height towards the centre of the heat transfer/radiation structure to form the appearance of a frustoconical shaped depression in the structure.

By changing the height of each ring, or by changing the height of individual fins, the heat transfer and convective heat dispersion into the surrounding air from the heat transfer/radiation structure can be optimised. Computer simulations have been conducted on each of the arrangements shown in FIGS. 9A to 9C and heat transfer plots of the results of the simulations are shown in FIGS. 10A to 10C, respectively. As can be seen in FIGS. 10A to 10C the arrangement shown in FIG. 9A is the most effective at overall heat transfer. However, the arrangement shown in FIG. 9C is most effective at dispersing the heat. For additional details see the two learned articles mentioned earlier.

FIG. 11 shows schematically a radiation fins arrangement as per FIG. 9A with a chimney 184 fitted on top of the heat transfer/radiation structure 172 in an attempt to further improve heat removal (i.e. cooling) efficiency. The chimney comprises a pipe section 186 with a flanged annular pate 188, such that when the chimney 184 is assembled onto the heat transfer/radiation structure 172 the flanged end 188 abuts a top surface of the fins. It is believed that the fin arrangement shown in FIG. 9A is most suited to being equipped with a chimney 184 because the fins, being all of the same height, provide a flush surface for the flange 88 to be seated on, and promotes a radially inwards and upwards directed draught of air that helps cooling the fins (i.e. convectively removing heat from module 100). It is believed that the by incorporating a chimney 184 onto a heat transfer/radiation structure 172 the cooling efficiency can be improved by around 20%, and this might also make it possible for the overall manufactured mass of the heat transfer/radiation structure to be reduced by up to 60% while maintaining the cooling efficiency of the structure.

The skilled person will appreciate that variations of the two embodiments described and illustrated are possible without departing from the inventive gist. For example, the housing 12, 112 need not be cylindrical, and ways of securing the top closure 70, 170, with its heat transfer constituent parts 72, 74, other than through a screw-cap type mechanism, are equally possible.

Turning lastly to FIG. 12, a modem/router module 100 very much in keeping with that of FIGS. 5 to 8 is shown, but with a modified bottom cap member 114′ which is devised to provide an integral mounting capability by way of a clamping arrangement 192.

The modem/router module 100 can be releasably secured to a top terminal end of vertical pole 190 by clamping movable clamping plate 194 against a stationary clamping plate 196 that is integrally formed with the bottom cap member 114′, with pole 190 between these clamping plates 194, 196, using a pair of clamping bolts 198 that when fastened/loosened cause displacement of movable clamping plate 194 to/from fixed clamping plate 196.

Clamping plates 194, 196 have contoured main plate portions 199 with reinforcing ribs 197 for increased rigidity and stability when the two clamping plates are secured to each other and clampingly sandwich the pole 190 there between.

It is to be understood that, if any prior art publication is referred to herein, such reference does not constitute an admission that the publication forms a part of the common general knowledge in the art, in Australia or any other country.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

Furthermore, relative reference terms such as ‘upper’, ‘lower’, ‘radially’, ‘axially’, ‘longitudinally’, etc are used herein for convenience in describing components and their relative positioning to each other. These terms should not be viewed as importing an essentiality unless the context dictates otherwise.

### REFERENCE SYMBOLS IN FIGURES

| | | | |
|---|---|---|---|
| 10, 100 | modem module | | |
| 12, 112 | Cylindrical main housing part | 113 | Externally threaded upper |
| | | | terminal rim 113 of 112 |
| 14 | Closed bottom end of 12 | 114 | Bottom closure element of 112 |
| 16, 116 | Open top end of 12 | 115 | Annular threaded bottom collar of 112 |
| 20 | PCB carrier | 116 | Annular bearing flange/gear ring |
| 22a | (PCBA) mmWave modem chip | 117 | Inner teeth ring at 116 |
| 22b | (PCBA) mmWave antenna module | 118 | Upper ring portion of 116 |
| 22c | Omni directional antennas | | |
| 22d | Ethernet controller chip | 127 | pinion driven by shaft of 126 |
| 24 | Ethernet controller chip | 128 | Circular support plate |
| 26, 126 | Rotary actuator for 20 | 125 | Annular skirt of 128 |
| 28 | Support fork for 20 | 129 | Mounting structure at 128 for 126 |
| 30, 130 | Thermal mitigation system | | |
| 40 | Interior finned heat spreader | 140 | Interior, non-finned heat spreader |
| 42 | Parallel radiating fins | | |
| 44 | Common top wall portion | 144 | Top plate 144 fixed to 140 |
| 46 | Common base plate portion | 146 | Discrete heat transfer bodies at 140 |
| 50 | Main Heat pipe | | |
| 51 | Horizontally bent portion of 50 | | |
| 52 | Upper heat pipe | | |
| 60 | Rotatable upper heat spreader | | |
| 62 | Concentric annular fins | | |
| 70, 170 | top closure cap integral with 72, 74 | 171 | Annular skirt of 170 |
| 72 | outer heat transfer/radiation | | |
| | structure of 70 | | |
| 74 | Inner heat sink/transfer structure of 70 | 190 | Vertical pole |
| 75 | Annular fins of 74 | | |
| 76 | plate-like circular base of 70 | | |
| 78 | Annular row of pins | | |
| 80 | Pins (heat radiators) | | |
| 184 | Chimney | | |
| 186 | Pipe section | | |
| 188 | Annular flange | | |

What is claimed is:

1. An outdoor-mountable, telecommunications module, comprising: an environmentally hardened housing; telecommunications equipment encased within the housing and disposed for rotation about an axis within the housing; and a thermal load mitigation system employing (i) a heat spreader structure for thermal conduction of heat away from at least some heat-generating components of the telecommunications equipment, to a rotatable heat sink structure received within the housing, (ii) an arrangement for primarily thermal conduction of heat across a small air gap between the rotatable heatsink structure and a non-rotating heat sink structure collocated within the housing, and (iii) an arrangement for convective heat dissipation into the environment from a radiator structure disposed outside of the housing and which is in direct thermal conductive arrangement with the non-rotating heat sink structure disposed inside of the housing.

2. The telecommunications module of claim 1, wherein the telecommunications module is a fixed wireless modem/router module, and wherein the telecommunications equipment comprises a PCB mounting mmWave antenna signal generation and processing components that include a plurality of said heat generating components as well as non-heat generating signal radiators/receivers (antennas).

3. The telecommunications module of claim 1, wherein the heat spreader structure further comprises an arrangement for the partial dissipation of heat it receives through thermal convection of heat into the inside of the housing.

4. The telecommunications module of claim 1, wherein the heat spreader structure comprises a finned or a non-finned metallic heat sink body thermally conductively coupled to at least some of the plurality of heat generating components as well as the rotatable heat sink structure.

5. The telecommunications module of claim 1, wherein the non-rotatable heat sink structure is present at, or forms integral part of a closure member arranged to close access into the inside of the housing.

6. The telecommunications module of claim 1, wherein the convective heat radiator disposed outside of the housing is present at or forms integral part of a or the closure member of the housing.

7. The telecommunications module of claim 5, wherein both the non-rotatable, housing-internal heat sink structure and the enclosure-external convective heat radiator are integrally formed with the closure member out of a metal material of high thermal conductivity.

8. The telecommunications module of claim 1, wherein the environmentally hardened housing is of generally cylindrical configuration and comprises a main housing part of a RF-transparent polymer which in use is deployed with its longitudinal axis in a generally vertical orientation, the housing having either an integral or otherwise sealingly engaged bottom cap, and wherein the housing further comprises a or the closure member in form of a top cap sealingly closing an upper opening of the main housing part.

9. The telecommunications module of claim 1, wherein the housing-internal rotatable heat sink structure and the housing-internal non-rotatable heat sink structure, for maintaining free relative rotational capacity between the two heat sink components and effective heat transfer, each comprise a plurality of concentric annular fins that interleave with each other in a manner that an as small as possible but rotation-enabling air gap is maintained between facing surfaces of the fins in operating conditions of the module.

10. The telecommunications module of claim 4, wherein the thermal mitigation system uses one or more heat pipes for assisting with the conductive heat transfer away from at least some of the heat generating components on the PCB, the heat pipe(s) being thermally coupled to the heat spreader body mounted to a rear face of the PCB and the upper, rotatable heat sink structure.

11. The telecommunications module of claim 1, wherein the housing-external convective heat radiator comprises a plurality of concentric rows of upstanding pin-like radiation elements spaced apart to maintain a predetermined small air gap with respect to each other, preferably no less than 1.0 mm, and more preferably around 1.5 to 2.5 mm.

12. The telecommunications module of claim 1, wherein the housing-external convective heat radiator comprises a plurality of fin-like structures extending spoke-like radially with respect to the longitudinal axis of the housing.

13. The telecommunications module of claim 1, further comprising a chimney or funnel structure at the housing on top of the housing-external heat radiation structure.

14. The telecommunications module of claim 1, further comprising a rotary actuator arrangement for imparting selective rotation to the PCB such as to orientate one or more of the antenna elements carried on the PCB into a desired RF-radiation direction.

15. The telecommunications module of claim 14 wherein the rotary actuator arrangement comprises an annular bearing flange configured as an annular gear element that is secured against movement within the housing, a support plate supported at the bearing flange for rotation about an axis of the bearing flange, and a motor fixed against movement in a suitable mounting structure of the support plate for rotation therewith, wherein actuation of the motor causes a driven pinion to rotationally move support plate through its interaction with the stationary gear ring.

16. The telecommunications module of claim 15, wherein the support plate is made from an electrically insulating metal or an electrically insulating, low friction polymer material.

17. The telecommunications module of claim 14, wherein the PCB is secured to a metallic block of the heat spreader structure which forms part of the thermal mitigation system, and wherein the metallic block is mounted to a top face of support plate for rotation therewith, such that rotation of support plate causes the PCB to re-orientate its main plane about the vertical rotation axis, in particular as a function of the geared engagement between motor pinion and stationary gear ring.

18. The telecommunications module of claim 1, wherein the environmentally hardened housing comprises a bottom closure cap devised to provide an integral mounting arrangement by way of which the module can be secured on top of a vertical pole enabling selective rotation about the vertical axis and fixing a rotational position of the housing.

19. The telecommunications module of claim 18, wherein the mounting arrangement comprises a movable clamping plate movable towards and away from a stationary clamping plate that is integrally formed with the bottom closure cap, the terminal end of the vertical pole locating between these clamping plates, wherein at least one clamping bolt cause displacement of movable clamping plate to/from the fixed clamping plate when rotated.
